(19) United States
(12) Patent Application Publication
(10) Pub. No.: US 2017/0179101 A1
(43) Pub. Date: Jun. 22, 2017

(54) BRIDGE STRUCTURE FOR EMBEDDING SEMICONDUCTOR DIE

(71) Applicants: SANDISK SEMICONDUCTOR (SHANGHAI) CO., LTD., Shanghai (CN); SANDISK INFORMATION TECHNOLOGY (SHANGHAI) CO., LTD., Shanghai (CN)

(72) Inventors: Junrong Yan, Shanghai (CN); Peng Lu, Shanghai (CN); Weili Wang, Shanghai (CN); Li Wang, Shanghai (CN); Pradeep Rai, Jangipur (IN); Jeff Xue, Shanghai (CN); Zhong Lu, Shanghai (CN)

(73) Assignees: SANDISK SEMICONDUCTOR (SHANGHAI) CO., LTD., Shanghai (CN); SANDISK INFORMATION TECHNOLOGY (SHANGHAI) CO., LTD., Shanghai (CN)

(21) Appl. No.: 15/446,930

(22) Filed: Mar. 1, 2017

Related U.S. Application Data
(63) Continuation of application No. 14/546,734, filed on Nov. 18, 2014.

(30) Foreign Application Priority Data
Dec. 3, 2013 (CN) 201310644104.1

(51) Int. Cl. H01L 25/00; H01L 23/544; H01L 25/065; H01L 21/304; H01L 23/13; H01L 21/78

(52) U.S. Cl. CPC H01L 25/50; H01L 23/13; H01L 21/78; H01L 25/0657; H01L 21/3043; H01L 23/544; H01L 2223/54426

(57) ABSTRACT

A semiconductor device, and a method of its manufacture, are disclosed. The semiconductor device includes a semiconductor die, such as a controller die, mounted on a surface of a substrate. A bridge structure is also mounted to the substrate, with the semiconductor die fitting within a trench formed in a bottom surface of the bridge structure. The bridge structure may be formed from a semiconductor wafer into either a dummy bridge structure functioning as a mechanical spacer layer, or an IC bridge structure functioning as both a mechanical spacer layer and an integrated circuit semiconductor die. Memory die may also be mounted atop the bridge structure.

### CLAIM OF PRIORITY

This application is a continuation application of U.S. patent application Ser. No. 14/546,734, filed Nov. 18, 2014, which application claimed priority to Chinese Patent Application No. 201310644104.1, filed Dec. 3, 2013, which applications are incorporated by reference herein in their entirety.

### BACKGROUND

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

While many varied packaging configurations are known, flash memory storage cards may in general be fabricated as system-in-a-package (SiP) or multichip modules (MCM), where a plurality of die are mounted and interconnected on a small footprint substrate. The substrate may in general include a rigid, dielectric base having a conductive layer etched on one or both sides. Electrical connections are formed between the die and the conductive layer(s), and the conductive layer(s) provide an electric lead structure for connection of the die to a host device. Once electrical connections between the die and substrate are made, the assembly is then typically encased in a molding compound which provides a protective package.

A cross-sectional side view and a top view of a conventional semiconductor package 20 are shown in FIGS. 1 and 2 (without molding compound in FIG. 2). Typical packages include a plurality of semiconductor die, such as flash memory die 22 and a controller die 24, affixed to a substrate 26. A plurality of die bond pads 28 may be formed on the semiconductor die 22, 24 during the die fabrication process. Similarly, a plurality of contact pads 30 may be formed on the substrate 26. Die 22 may be affixed to the substrate 26, and then die 24 may be mounted on die 22. All die may then be electrically coupled to the substrate by affixing wire bonds 32 between respective die bond pad 28 and contact pad 30 pairs. Once all electrical connections are made, the die and wire bonds may be encapsulated in a molding compound 34 to seal the package and protect the die and wire bonds.

In order to most efficiently use package footprint, it is known to stack semiconductor die on top of each other, either completely overlapping each other, or with an offset as shown in FIGS. 1 and 2. In an offset configuration, a die is stacked on top of another die so that the bond pads of the lower die are left exposed. An offset configuration provides an advantage of convenient access of the bond pads on each of the semiconductor die in the stack. While two memory die are shown in the stack in FIG. 1, it is known to provide more memory die in the stack, such as for example four or eight memory die.

In order to increase memory capacity in semiconductor packages while maintaining or reducing the overall size of the package, the size of the memory die has become large compared to the overall size of the package. As such, it is common for the footprint of the memory die to be almost as large as the footprint of the substrate.

The controller die 24 is generally smaller than the memory die 22. Accordingly, the controller die 24 is conventionally placed at the top of the memory die stack. This configuration has certain drawbacks. For example, is difficult to form a large number of wire bonds from the die bond pads on the controller die down to the substrate. It is known to provide an interposer or redistribution layer beneath the controller die so that wire bonds are made from the controller die to the interposer, and then from the interposer down to the substrate. However, this adds cost and complexity to the semiconductor device fabrication. Moreover, the relatively long length of the wire bonds from the controller die to the substrate slows down operation of the semiconductor device.

### DESCRIPTION OF THE DRAWINGS

FIG. 1 is a prior art edge view of a conventional semiconductor device including a pair of semiconductor die stacked in an offset relation.

FIG. 2 is a prior art edge view of a conventional semiconductor device including a pair of semiconductor die stacked in an overlapping relation and separated by a spacer layer.

FIG. 3 is a flowchart for forming a semiconductor die according to embodiments of the present invention.

FIG. 4 is a perspective view of a stage in the fabrication of a semiconductor device according to a first embodiment of the present technology.

FIG. 5 is a perspective view of a further stage in the fabrication of a semiconductor device according to a first embodiment of the present technology.

FIG. 5A is a perspective view of a stage in the fabrication of a semiconductor device according to an alternative embodiment of the present technology.

FIG. 6 is a flowchart for forming a bridge wafer according to embodiments of the present technology.

FIGS. 7-9 are top, perspective and bottom views of a partially processed wafer including trenches according to an embodiment of the present technology.

FIGS. 10-13 are different views of a dummy bridge structure according to the first embodiment of the present technology.

FIG. 14 is an edge view of a bridge structure according to embodiments of the present technology.

FIG. 15 is a perspective view of a further stage in the fabrication of a semiconductor device according to a first embodiment of the present technology.

FIG. 16 is a perspective view of a further stage in the fabrication of a semiconductor device according to a first embodiment of the present technology.

FIG. 17 is a perspective view of a further stage in the fabrication of a semiconductor device according to a first embodiment of the present technology.

FIGS. 18 and 19 are flowcharts of alternative methods for forming an IC bridge structure according to a second embodiment of the present technology.

FIGS. 20 and 21 are top and bottom views of an IC wafer including trenches according to an embodiment of the present technology.

FIGS. 22-25 are different views of an IC bridge structure according to the second embodiment of the present technology.

FIG. 26 is a perspective view of a stage in the fabrication of a semiconductor device according to the second embodiment of the present technology.

FIG. 27 is a perspective view of a further stage in the fabrication of a semiconductor device according to the second embodiment of the present technology.

FIG. 28 is a perspective view of a further stage in the fabrication of a semiconductor device according to the second embodiment of the present technology.

FIG. 29 is a perspective view of a further stage in the fabrication of a semiconductor device according to the second embodiment of the present technology.

FIG. 30 is a perspective view of a stage in the fabrication of a semiconductor device according to an alternative embodiment of the present technology.

FIG. 31 is a perspective view of a stage in the fabrication of a semiconductor device according to a further alternative embodiment of the present technology.

FIGS. 32-33 illustrate views of further alternative embodiments of the bridge structure according to embodiments of the present technology.

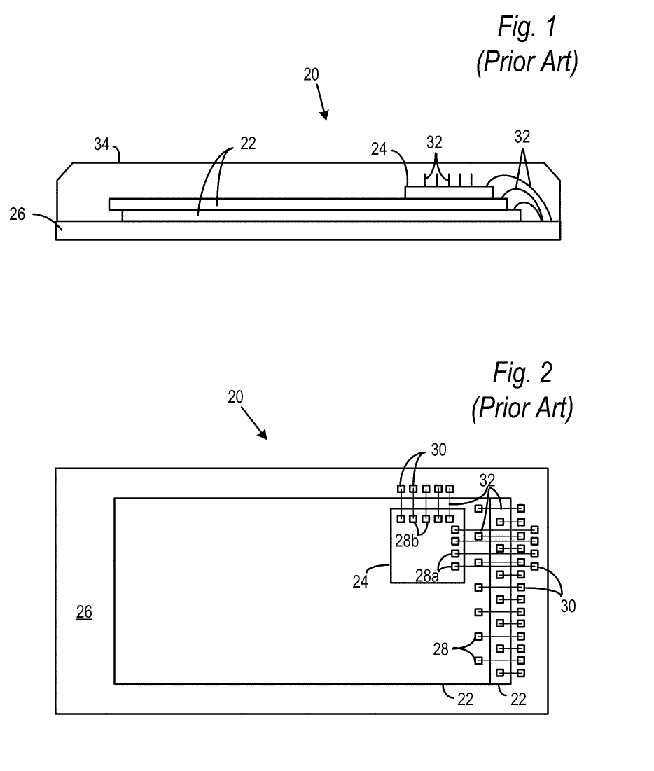

### DETAILED DESCRIPTION

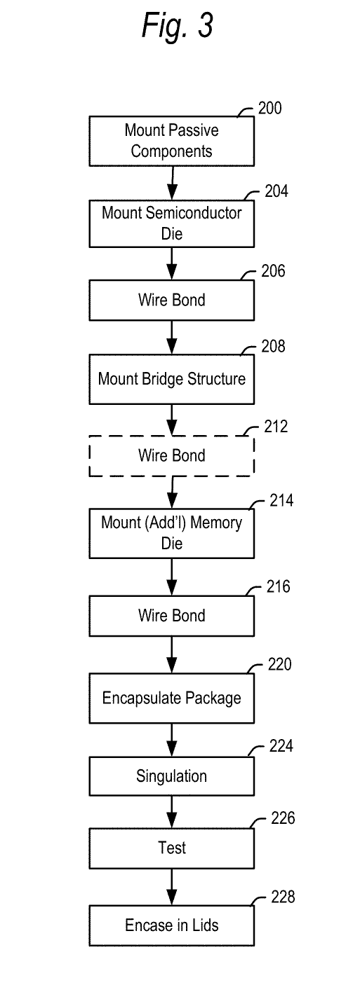

The present technology will now be described with reference to FIGS. 3 through 33, which in embodiments, relate to a semiconductor device including a semiconductor die, such as a controller, mounted on a surface of a substrate. A bridge structure is also mounted to the substrate, with the semiconductor die fitting within a trench formed in a bottom surface of the bridge structure. The bridge structure may be formed and cut from a semiconductor wafer into one of two different types of bridge structures.

A first bridge structure, referred to herein as a dummy bridge structure, is formed from a semiconductor wafer and functions as a mechanical spacer layer. In this embodiment, the semiconductor wafer may include rows of trenches in one major surface, and no integrated circuits in the opposite major surface. Respective semiconductor die may then be diced from the wafer into dummy bridge structures and affixed to the substrate.

A second bridge structure, referred to herein as an IC bridge structure, is formed from a semiconductor wafer and functions as both a mechanical spacer layer and an integrated circuit semiconductor die. IC bridge structures may be fabricated by at least two methods. In a first method, integrated circuits are processed on one major surface of the semiconductor wafer and trenches are formed in the opposite major surface but only after being aligned with the integrated circuits on the opposite major surface. In a second method, trenches are formed in one major surface of the semiconductor wafer and integrated circuits are formed on the opposite major surface but only after being aligned with the trenches in the opposite major surface. Respective semiconductor die formed by either the first or second methods may then be diced from the wafer into IC bridge structures and affixed to the substrate. Further details of the bridge structures of these embodiments are explained below.

It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top” and “bottom,” “upper” and “lower” and “vertical” and “horizontal” as may be used herein are by way of example and illustrative purposes only, and are not meant to limit the description of the invention inasmuch as the referenced item can be exchanged in position and orientation. Also, as used herein, the terms “substantially” and/or “about” mean that the specified dimension or parameter may be varied within an acceptable manufacturing tolerance for a given application. In one embodiment, the acceptable manufacturing tolerance is ±0.25%.

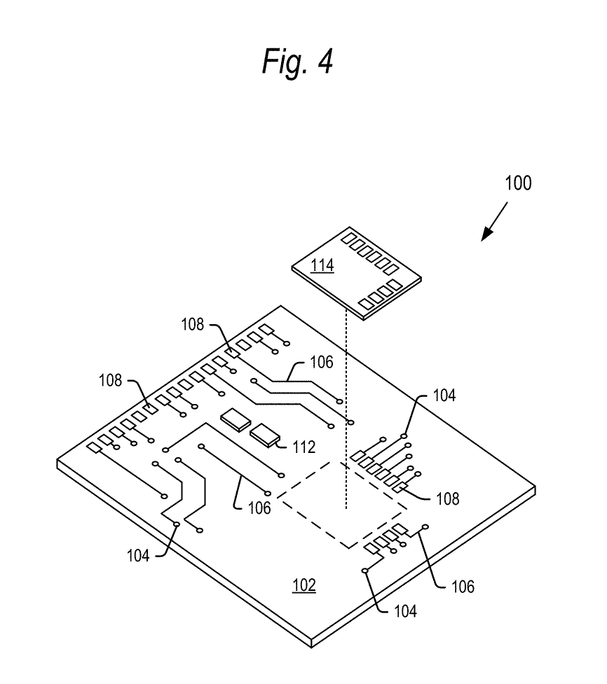

An embodiment of the present invention will now be explained with reference to the flowcharts of FIGS. 3, 6, 18 and 19, and the views of FIGS. 4-5, 7-17 and 20-33. Although the figures show an individual semiconductor device 100, or a portion thereof, it is understood that the device 100 may be batch processed along with a plurality of other devices 100 on a substrate panel to achieve economies of scale. The number of rows and columns of semiconductor devices 100 on the substrate panel may vary.

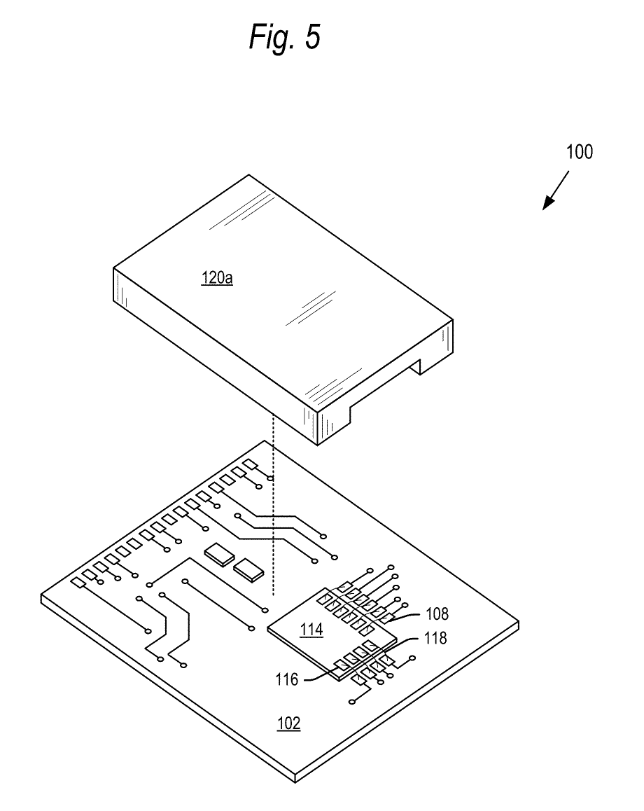

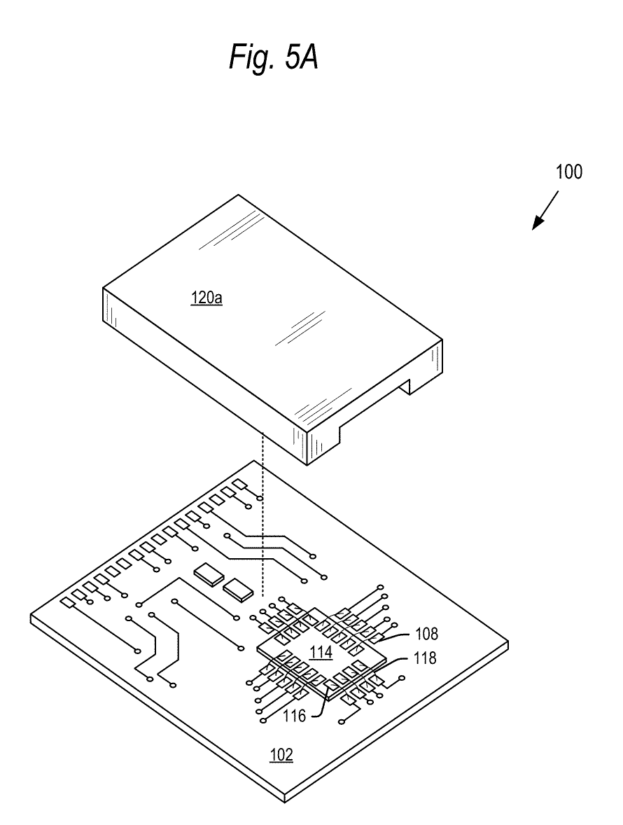

The substrate panel may begin with a plurality of substrates 102 (again, one such substrate is shown in FIGS. 4-5 for example). The substrate 102 may be a variety of different chip carrier mediums, including a printed circuit board (PCB), a leadframe or a tape automated bonded (TAB) tape. The substrate may include a plurality of vias 104, electrical traces 106 and contact pads 108. The substrate 102 may include many more vias 104, traces 106 and pads 108 (only some of which are numbered in the figures), and they may be in different locations than are shown in the figures.

Referring to the flowchart of FIG. 3, passive components 112 may be affixed to the substrate 102 in a step 200. The one or more passive components may include for example one or more capacitors, resistors and/or inductors, though other components are contemplated. The passive components 112 shown (only one of which is numbered in the figures) are by way of example only, and the number, type and position may vary in further embodiments. The passive components 112 may extend above the surface of the substrate 102. As such they may be mounted outside of the footprint of the memory die stack explained below. Alternatively, the passive components may be positioned on the substrate 102 so as to fit within a trench of a bridge structure mounted on the substrate as is also explained below. As shown in the figures, the passive components 112 may fit within the trench in the bridge structure.

In step 204, a semiconductor die 114 may be mounted on a surface of the substrate 102. As explained below, the semiconductor die 114 may also be positioned on the substrate 102 so as to fit within the trench of the bridge structure when the bridge structure is mounted on the substrate. The semiconductor die 114 may be a controller ASIC. However, die 114 may be other types of semiconductor die, such as a DRAM or NAND.

FIG. 5 shows the semiconductor die 114 mounted on the substrate 102. The semiconductor die 114 includes die bond pads 116, one of which is labeled for example in FIG. 5. The die bond pads 116 may be electrically coupled to contact pads 108 on the substrate 102 via wire bonds 118 in a wire bond step 206. It is understood that the semiconductor die 114 may be electrically coupled to the substrate 102 using other technologies. For example, semiconductor die 114 may be a flip-chip which is soldered onto contact pads of the substrate 102. As a further example, conductive leads may be printed by known printing processes between the die bond pads and contact pads to electrically couple the semiconductor die 114 to the substrate 102.

The number of die bond pads 116 and wire bonds 118 shown is for clarity only, and it is understood that there may be more contact pads 108, die bond pads 116 and wire bonds 118 in further embodiments. Moreover, while semiconductor die 114 is shown with die bond pads and wire bonds on only two sides in FIG. 5, it is understood that semiconductor die 114 may have die bond pads and wire bonds on all four sides of the semiconductor die 114 in further embodiments, for example as shown in FIG. 5A. The semiconductor die 114 may alternatively have die bond pads 116 and wire bonds 118 on one side or three sides in further examples.

In accordance with the present technology, a bridge structure 120 may next be mounted to the substrate 102 in step 208. The bridge structure 120 is formed with a trench in a bottom surface. The bridge structure 120 may be mounted on the substrate 102 so that the semiconductor die 114 (and possibly other structures on the surface of substrate 102) sit within the trench. It is a feature of the present technology that the bridge structures are formed from a semiconductor wafer. One advantage of this feature is that the bridge structure may be made of the same material as other semiconductor die mounted on top of the bridge structure as explained hereinafter, thereby avoiding thermal mismatch. A further advantage is that the fabrication facilities that make the semiconductor device 100 typically have tools and processes for handling semiconductor wafers. Thus, formation of the bridge structures 120 from a semiconductor wafer involves minimal additional cost and processing steps for the fabrication facility.

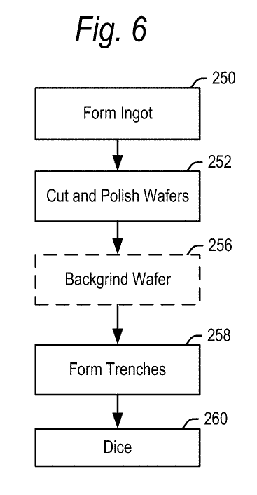

Referring now to FIGS. 6-8, dummy bridge structures 120a according to a first embodiment may be formed from semiconductor wafer 300. A semiconductor wafer 300 starts as an ingot of wafer material which may be formed in step 250. In one example, the ingot from which the wafers 300 are formed may be monocrystalline silicon grown according to either a Czochralski (CZ) or floating zone (FZ) process. However, as explained below, in embodiments where the finished bridge structures are purely mechanical spacer layers, such as in FIG. 6, the ingot from which wafer 300 is formed may be polycrystalline silicon or any polycrystalline semiconductor material in order to reduce the cost of the material of such dummy bridge structures.

In addition to silicon, it is understood that wafer 300 may be formed of any other semiconductor element or compound including but not limited to Group IV elemental semiconductors, Group IV compound semiconductors, Group VI elemental semiconductors, semiconductors; II-VI semiconductors, I-VII semiconductors, IV-VI semiconductors, V-VI semiconductors, and II-V semiconductors. Additionally, as the wafer 300 is used to form a spacer layer in the embodiment of FIG. 6, the dummy bridge structure 120a may be a variety of materials beyond semiconductor elements or compounds.

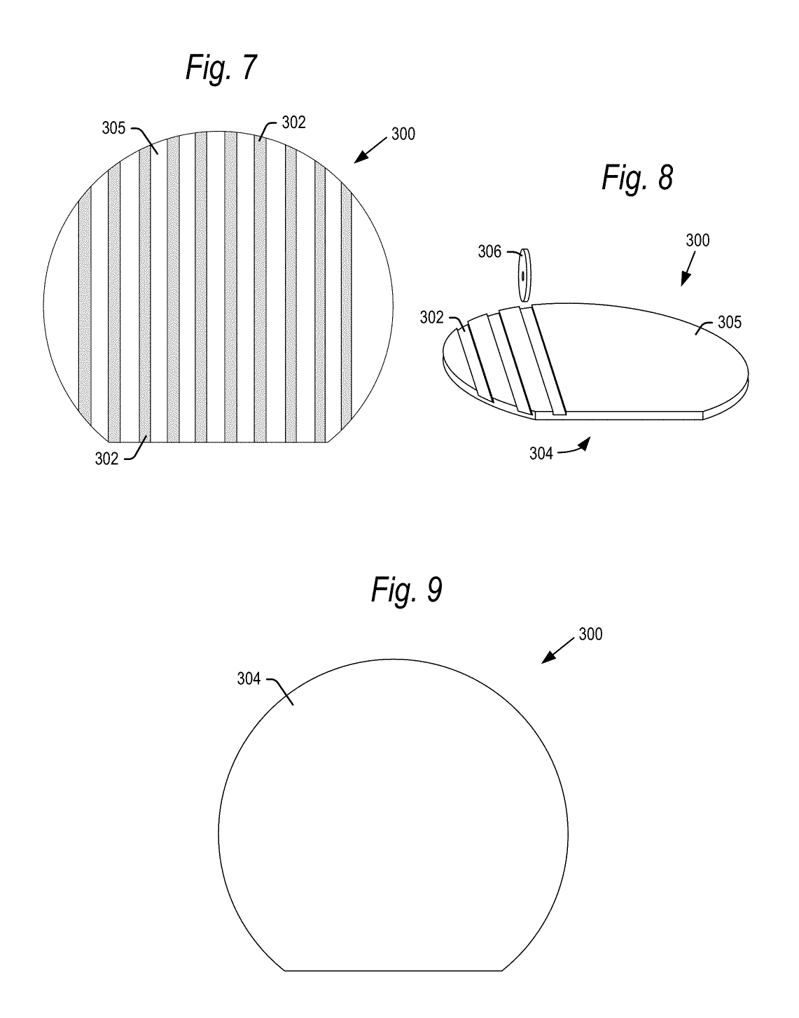

In step 252, the semiconductor wafer 300 may be cut from an ingot and polished on both major surfaces to provide smooth surfaces. Wafer 300 may have a first major surface 304 (FIG. 9) and an opposite second major surface 305 (FIG. 7). In step 256, a grinding wheel may be applied to the second major surface 305 to backgrind the wafer 300 from, for example, 780 μm to 280 μm, though these thicknesses are by way of example only and may vary in different embodiments. This step is shown in dashed lines as this step may be skipped in embodiments and the wafer 300 left at the thickness at which it is cut. It is also conceivable that the backgrind step 256 be performed later in the process, for example after the trench-forming step explained below.

In step 258, trenches 302 (some of which are numbered in FIGS. 7 and 8) are formed into the second major surface 305 of wafer 300. In embodiments, the trenches may be 6 mm wide and extend in parallel lengths across the second major surface 305. The trenches 302 are spaced apart from each other such that, once the wafer is diced as explained below, each trench 302 is positioned in the same location in a bottom surface of the resultant semiconductor dies. For example, in one embodiment, the diced bridge structures 120 each have a width of 12 mm. In such an example, the trenches 302 may be spaced apart 12 mm (center to center) and formed so as to be in the middle of the width of the bridge structure. Thus, a 12 mm wide bridge structure would have a 6 mm wide trench, with 3 mm on either side of the trench. It is understood that each of these dimensions is by way of example only, and that each may vary in further embodiments. Moreover, while the trenches 302 are centered in each bridge structure in one embodiment, it is understood that trenches 302 may instead be closer to one edge or the other across the width of the bridge structure in further embodiments.

The trench 302 may be formed to a depth of between 150 μm to 200 μm. It is understood that the trench 302 may be formed deeper or shallower than that, with the provision that the trench be deep enough to be positioned over the semiconductor die 114, and any wire bonds formed thereon, without contact between the trench walls and semiconductor die/wire bonds.

The trench 302 may be formed by a variety of different technologies. In one example, the trench 302 may be formed with a saw blade 306 (FIG. 8) performing a “half-cut” into the surface of the wafer 300; that is, into the surface, but not completely through the thickness of the wafer. The saw blade is shown in FIG. 8 having formed some but not all of the trenches 302. The thickness of the saw blade 306 in this example may vary. In one example, the saw blade 306 may be 60 μm wide. Such a saw blade may make 100 passes to form a single trench 6 mm wide and of uniform depth in the wafer 300. That process may be repeated for all trenches across the width of wafer 300.

It is understood that the thickness of the blade may be different in further embodiments. For example, the blade may be 1.0 mm (6 passes to form a 6 mm wide trench of uniform depth), 2.0 mm (3 passes to form a 6 mm wide trench of uniform depth) or 6.0 mm (a single pass to form a 6 mm wide trench of uniform depth). Other blade thicknesses are contemplated.

In a further embodiment, the trench 302 may be formed in a milling process having a circular milling bit (not shown). Where the saw blade 306 makes the half cuts with an axis of rotation parallel to the second major surface 305 of the wafer 300, the milling bit makes the half cuts with an axis of rotation perpendicular to the second major surface 305. The milling bit may for example have a diameter of 6.0 mm and a thickness of at least the depth of the trench 302 so that each trench 302 may be formed in a single pass of the milling bit. The milling bit may have a smaller diameter in further embodiments so as to take more than one pass to form a single trench of uniform depth.

In a further embodiment, it is contemplated that a laser (not shown) be used to form the trenches 302. In one such example, a low power CO₂ laser may be used to ablate a portion of the wafer to make the desired half-cut in the second major surface 305. The laser may form each trench in a single pass or multiple passes, depending on the diameter of the laser beam used.

In a further embodiment, the trenches 302 may be etched in the second major surface 305 of the wafer 300. The trenches may be etched in a variety of different processes, including for example using a liquid etchant, a dry plasma etchant, or a vapor etchant. In one example, a photoresist (not shown) is applied across the entire second major surface 305. Using one of the mask alignment methods explained hereinafter, the photoresist (not shown) on second major surface 305 is next exposed to an aligned trench mask (not shown) by use of ultra violet light. The photoresist (not shown) is then developed which results in the optical pattern of the trench mask being transferred as open windows (not shown) in the photoresist. The entire second major surface 305 of the wafer 300 is then exposed to a selective etch that cuts trenches in the second major surface 305 without affecting the photoresist. The photoresist is removed in a stripping process to yield the trenches 302 in the second major surface 305.

In one embodiment, the process for etching trenches 302 may be an anisotropic etch which can result in trenches 302 having rectangular or approximately rectangular sidewalls. In further embodiments, the process may be an isotropic etch which can result in trenches 302 having more rounded sidewalls. The concentration of the etchant and time that the etchant is left on the wafer 300 may both be controlled to provide the trenches 302 with the desired depth and dimensions.

As noted above, the depth of the trenches 302 in one embodiment may be between 150 μm to 200 μm. In one example, a trench 302 may be formed to this depth all at once. Thus, in an example where a trench 302 is cut using a 60 μm wide saw blade, a 6 mm trench may be fully cut to the desired depth in 100 width-wise passes of the blade. In further embodiments, it is contemplated that each cut (or laser or etching process) only be to a partial depth. For example, where trench 302 is 150 μm deep, there may be three separate partial-depth cuts, a first down to 50 μm, a second down to 100 μm, and a third down to 150 μm. The number of partial cuts/lasings/etchings to form the full depth may vary above or below three in further embodiments.

Thus, in an example of a 6 mm trench cut with a 60 μm saw, where the depth is formed in three partial cuts, there may be a total of 300 cuts made to form the trench—a first set of 100 cuts across the width to a first partial depth, a second set of 100 cuts across the width to a second partial depth, and a third set of 100 cuts across the width to a third partial depth. Again, these numbers are by way of example, and there may be different numbers of width-wise and partial depth cuts. Instead of making successive cuts across the width, and then repeating at a new depth, a trench 302 may be formed by making successive cuts down to full depth, and then repeating across the width of the trench.

In the embodiment described with respect to FIG. 6, the first major surface 304 of the wafer 300 is not processed to include integrated circuits. In such an embodiment, there may be no need to align the trenches 302 on the second major surface 305 to the first major surface 304 when determining where to position the trenches on the second major surface 305. In such an embodiment, the trenches may be formed as explained above, and then, with the second major surface 305 facing upward, the wafer 300 may be scribed and diced in step 260 into individual semiconductor die, each forming a dummy bridge structure 120a. It is conceivable that the first major surface 304 may include features with which the trench positions on the second major surface 305 need to be aligned before the trenches 302 are formed. Various embodiments for aligning the trenches on the second major surface 305 with features on the first major surface 304 are described hereinafter.

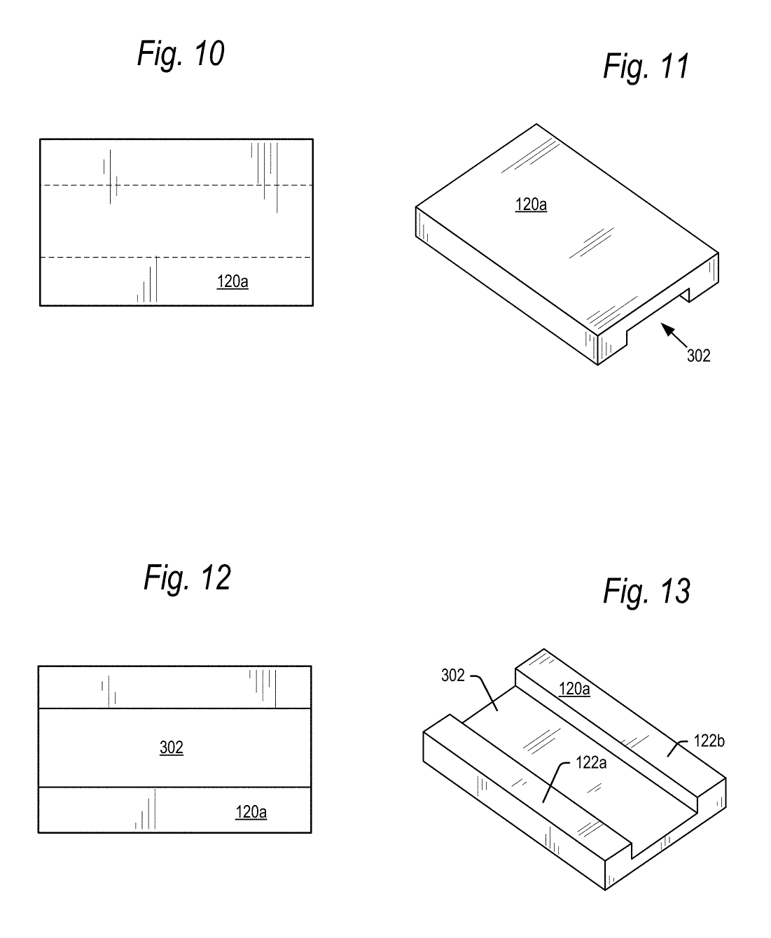

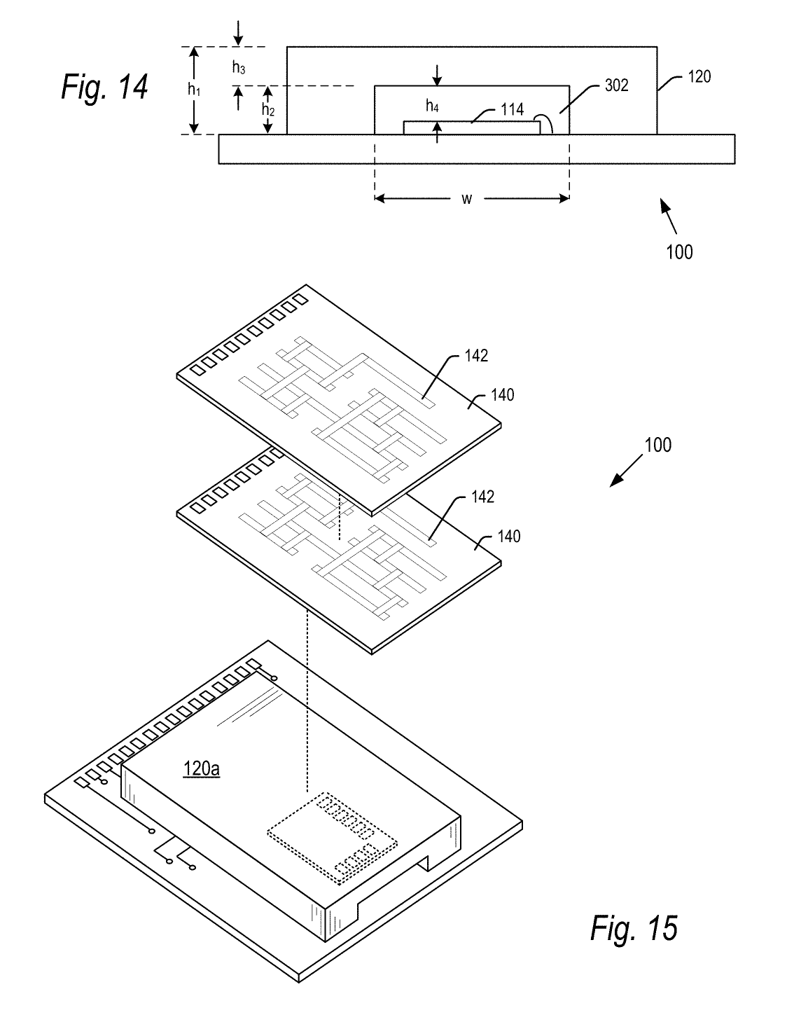

In the embodiment of FIG. 6, no integrated circuits are formed on wafer 300 before dicing, and the finished dummy bridge structures 120a function as mechanical spacer layers having no electrical function. FIGS. 10 and 11 show top and top perspective views of a finished dummy bridge structure 120a including trench 302. FIGS. 12 and 13 show bottom and bottom perspective views of a finished dummy bridge structure 120a including trench 302. FIG. 14 shows an edge view of the dummy bridge structure 120a after being mounted on the substrate 102 in step 208 (FIG. 3). As seen in FIG. 13, the trench 302 defines rails 122a and 122b in a lower surface of the bridge structure 120a. In embodiments, the rails 122a, 122b extend the entire length of the bridge structure 120a. The dummy bridge structure 120a may be affixed to the substrate 102 via an adhesive such as die attach film on the rails 122a, 122b.

FIG. 14 also shows semiconductor die 114 positioned within trench 302. The relative sizes of trench 302 and semiconductor die 114 are by way of example and may not be drawn to proportion. In one example, semiconductor die 114 may have a width of about 5 mm. With wire bonds 118 off one or more edges of the semiconductor die 114, the semiconductor die 114 and wire bonds may fit within a trench having a width, w, of 6 mm as noted above. These dimensions may all vary provided the trench is large enough to accommodate the semiconductor die 114 and wire bonds (if present).

As noted above, the height, h₁, of the bridge structure 120 may for example be about 280 μm, and the height, h₂, of the trench 302 may for example range from 76 μm to 127 μm. This leaves a height, h₃, of the bridge structure above the trench of 153 μm to 204 μm. Each of these dimensions is by way of example only and may vary in further embodiments. The semiconductor die 114 may have a thickness of 46 μm. The die attach film attaching the semiconductor die 114 may have a thickness of 10 μm, and the die attach film attaching the bridge structure 120 may have a thickness of 20 μm. With these dimensions, there may be a space, h₄, within the trench 302 over the semiconductor die 114 ranging from 117 μm to 168 μm. This space is large enough for wire bonds that may be used. These dimensions may vary in further embodiments. For example, in further embodiments, the space h₄, may be 106 μm.

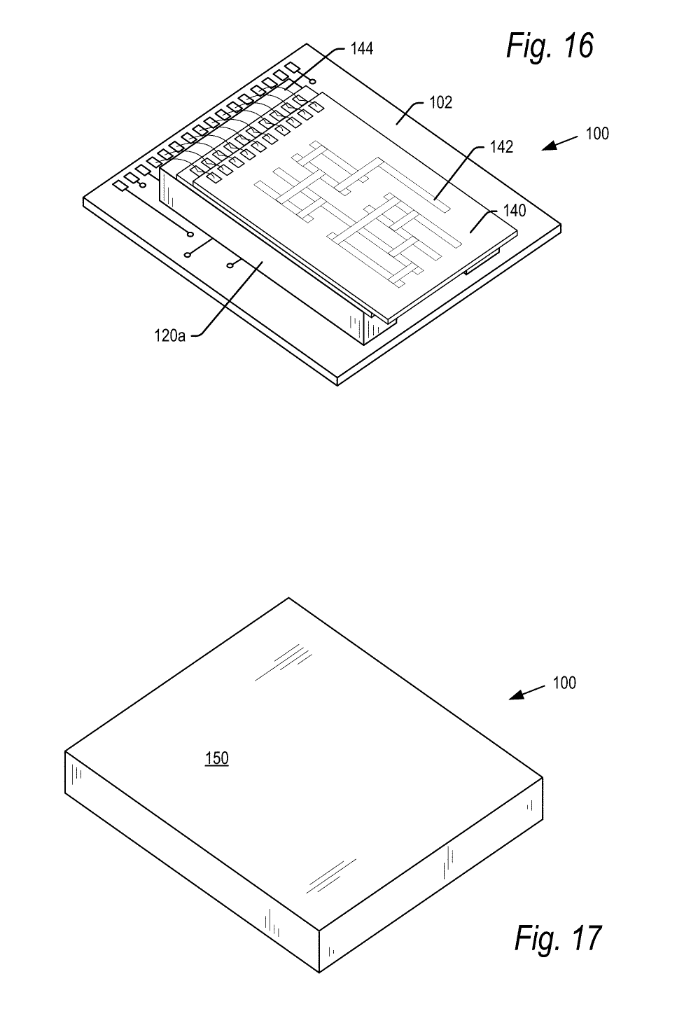

Referring again to the flowchart of FIG. 3 and perspective view of FIG. 15, one or more semiconductor die 140 may be stacked on top of the dummy bridge structure 120a in step 214. Step 212 of wire bonding the bridge structure 120 is shown in dashed lines as this step would be skipped in embodiments where the bridge structure has no electrical function. As shown in FIG. 16, the semiconductor die 140 may be stacked in stepped configuration. While two such semiconductor die 140 are shown, there may be a single semiconductor die 140 or more than two semiconductor die in the die stack in further embodiments. Semiconductor die 140 may include integrated circuits 142 functioning for example as memory die and more preferably NAND flash memory die, but other types of semiconductor die are contemplated.

In step 216, the semiconductor die 140 may be wire bonded to contact pads 108 on the substrate 102 via wire bonds 144 in a known wire bonding process, using for example a wire bond capillary (not shown).

After the die stack is formed and wire bonded to contact pads 108 on the substrate 102, the semiconductor device 100 may be encased within the molding compound 150 in step 220, and singulated from the panel in step 224, to form a finished semiconductor device 100 as shown in FIG. 17. Molding compound 150 may be a known epoxy such as for example available from Sumitomo Corp. and Nitto Denko Corp., both having headquarters in Japan. Thereafter, the device 100 may undergo electrical test and burn-in in step 226. In some embodiments, the finished semiconductor device 100 may optionally be enclosed within a lid (not shown) in step 228.

The dummy bridge structure 120a described with respect to FIGS. 6-17 is a spacer layer, formed from a partially processed wafer having no integrated circuits. The dummy bridge structure 120a allows the semiconductor die 114 (and possibly other components) to be mounted on and extend above the surface of the substrate, while providing a flat surface on which to mount the memory die stack.

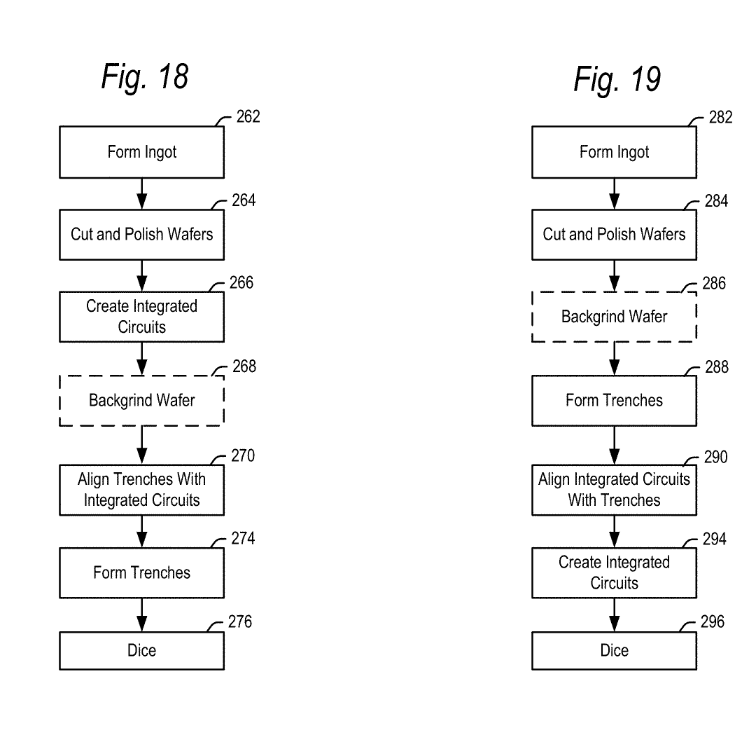

However, as noted, the bridge structure 120 may alternatively be an IC bridge structure 120b, formed from a semiconductor wafer having integrated circuits. Such an embodiment may be fabricated at least two ways. In a first fabrication process, the integrated circuits are formed on the first major surface 304 of the wafer 300 prior to the trenches 302 being formed in the opposed second major surface 305. This embodiment is described with reference to the flowchart of FIG. 18 and figures thereafter. In a second fabrication process, the trenches in the second major surface 305 are formed prior to the integrated circuits being formed in the opposed first major surface 304. This embodiment is described with reference to the flowchart of FIG. 19 and figures thereafter.

Referring now to the flowchart of FIG. 18, wafer 300 may be cut from an ingot which is formed in step 262. The ingot from which the wafers 300 are formed in this embodiment may be monocrystalline silicon grown according to either a CZ or FZ process. While silicon is one example, the ingot may more generally be formed of any other semiconductor element or compound including hut not limited to Group IV elemental semiconductors, Group IV compound semiconductors, Group VI elemental semiconductors, III-V semiconductors, II-VI semiconductors, I-VII semiconductors, IV-VI semiconductors, V-VI semiconductors, and II-V semiconductors.

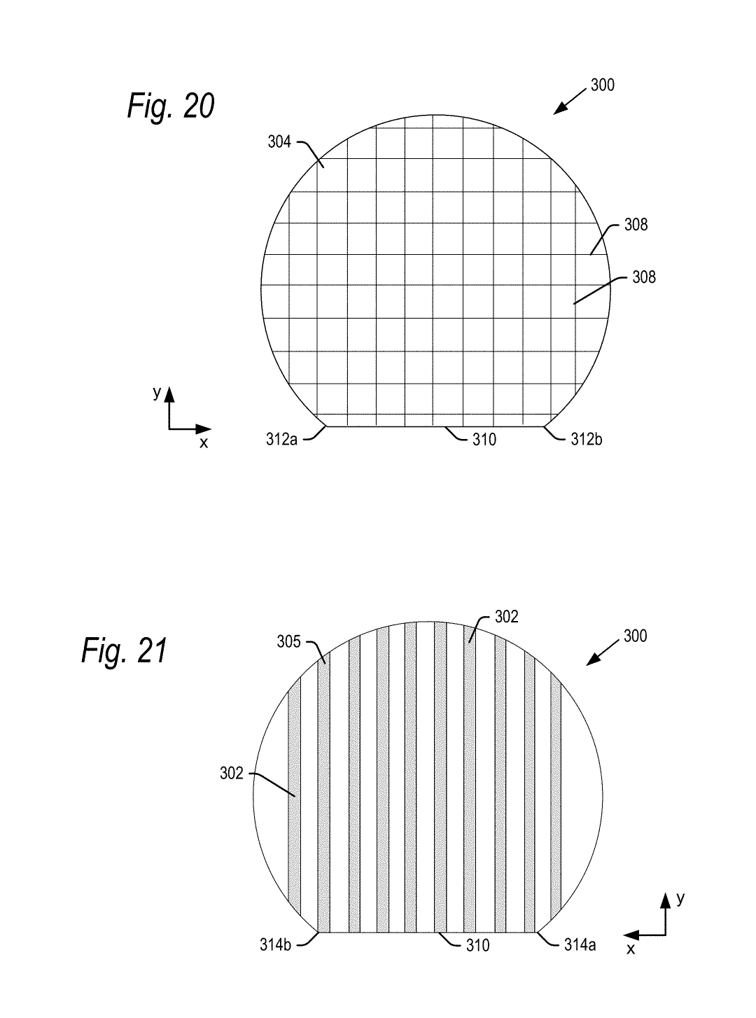

In step 264, the semiconductor wafer 300 may be cut from an ingot and polished on both the first major surface 304 (FIG. 20) and second major surface 305 (FIG. 21) to provide smooth surfaces. In step 266, the first major surface may undergo various processing steps to form integrated circuits on and in the first major surface. The steps may include scribing the first major surface 304 with vertical and horizontal scribe lines 308 to assist in the dicing of respective semiconductor die from wafer 300. In embodiments, the integrated circuits may operate as NAND flash memory semiconductor die, though other types of integrated circuits are contemplated.

In step 268, a grinding wheel may be applied to the second major surface 305 to backgrind the wafer 300 from, for example, 780 μm to 280 μm, though these thicknesses are by way of example only and may vary in different embodiments. As above, this step may be omitted or performed at a later stage in wafer 300 processing.

In step 270, the trenches 302 disposed in the second major surface 305 may be aligned with respect to the respective integrated circuits formed in the first major surface 304. This alignment may be done by a number of different methods. In one example, the positions of the integrated circuits on the first major surface 304 are known with respect to a selected point on the surface 304, and the position of the selected point on surface 304 is known with respect a corresponding selected point on the opposite surface 305. In this instance, the positions of the trenches 302 on the second major surface 305 may be aligned to the integrated circuits on the first surface 304 by aligning the positions of the trenches to the selected point on the second major surface 305.

For example, wafer 300 typically includes a flat 310 (FIGS. 20-21) for identifying and orienting the crystalline structure of the wafer for processing. The flat 310 ends at points, referred to as cleave points, where the rounded portion of the wafer 300 meets the flat 310. First major surface 304 has cleave points 312a and 312b, and second major surface 305 has cleave points 314a and 314b. Cleave point 312a on surface 304 aligns over cleave point 314a on surface 305 (they are shown flipped with respect to each other in the views of FIGS. 20 and 21 as the wafer 300 is flipped over in the view of FIG. 21 relative to FIG. 20). The same is true of cleave points 312b and 314b.

The positions of the integrated circuits on the first major surface 304 may be formed in a known relation with respect to at least one of the cleave points, for example, cleave point 312a. The position of cleave point 312a on the first major surface 304 is known with respect to the position of cleave point 314a on the second major surface 305. Thus, the positions of the trenches 302 in the second major surface 305 may be set at predetermined distances with respect to the cleave point 314a so as to ensure alignment of the trenches 302 in the second major surface 305 with respect to the integrated circuits in the first major surface 304.

In a further embodiment, with the second major surface 305 facing upward, an IR (infrared) camera may be used to image through the wafer in order to line up the trench positions on the second major surface with the integrated circuits on the first major surface. Infrared rays have a longer wavelength compared with visible light and have less scatter. It is thus possible to image features of the integrated circuits on the first major surface 304 from the second major surface 305. This allows the positions of the trenches in the second major surface 305 to be defined in proper alignment with the integrated circuits on the first major surface 304. Such technology for aligning between the first and second major surfaces of a wafer is known for example from Disco Corporation having a place of business in Tokyo, Japan.

It is understood that other technologies may be used to align the integrated circuits on the first major surface of wafer 300 to existing trenches 302 on the second major surface of wafer 300, or to align the trenches 302 on the second major surface to existing features on the first major surface. Further examples of such technologies are described in U.S. Pat. No. 5,530,552, entitled, “Double Sided Wafer, Alignment Technique,” issued Jun. 25, 1996, and in U.S. Pat. No. 8,283,256, entitled “Methods of Forming Microdevice Substrates Using Double-Sided Alignment Techniques,” issued Oct. 9, 2012. Both of these patents are incorporated by reference in their entireties herein.

Once the positions of the trenches are properly aligned with respect to the respective integrated circuits on the first major surface, the trenches 302 may be formed in the second major surface 305 in step 274, as shown in the view of the second major surface 305 in FIG. 21. The trenches may be formed in the same manner as any of the embodiments described above. After formation of the trenches 302, the wafer 300 may be scribed and diced into individual semiconductor dies in step 276. Each diced IC bridge structure 120b may function as a spacer layer and an integrated circuit semiconductor die as explained below.

FIG. 19 describes an alternative fabrication process for forming IC bridge structures 120b. The wafer 300 may be cut from an ingot in step 282 which is formed as described above, and the wafer 300 may be cut and polished from the ingot in step 284 as described above. The cut wafer may undergo a backgrind process in step 286, though this process may be omitted or performed later in the fabrication process in further embodiments. In step 288, trenches 302 may be formed on the second major surface 305 of wafer 300 in accordance with any of the embodiments described above.

In step 290, the masks for forming the integrated circuits on the first major surface 304 may be aligned with respect to the trenches 302 on the second major surface 305. This alignment may be performed using any of the above-described methods for aligning between the first and second major surfaces 304, 305. Once the positions of the integrated circuits are set in alignment with the trenches, the integrated circuits may be formed in and on the first major surface of the wafer 300 in step 294. As above, the integrated circuits may form NAND flash memory, but other integrated circuits are contemplated. After formation of the integrated circuits, the wafer 300 may be scribed and diced to create the plurality of semiconductor die in step 296. Each semiconductor die may be an IC bridge structure 120b as explained below.

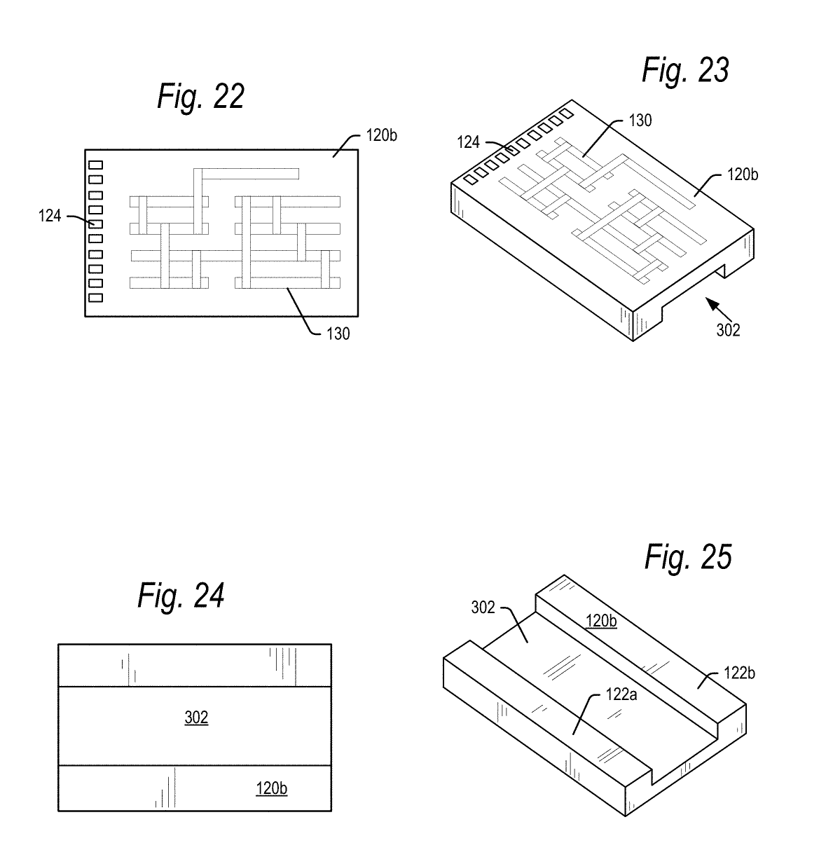

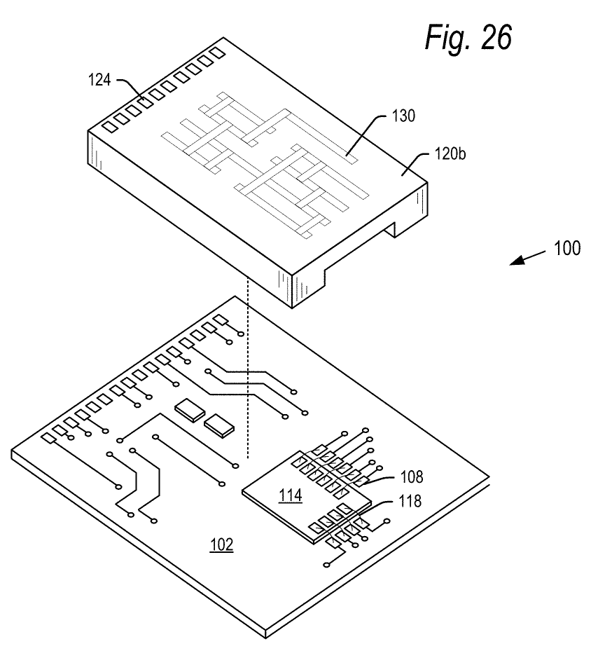

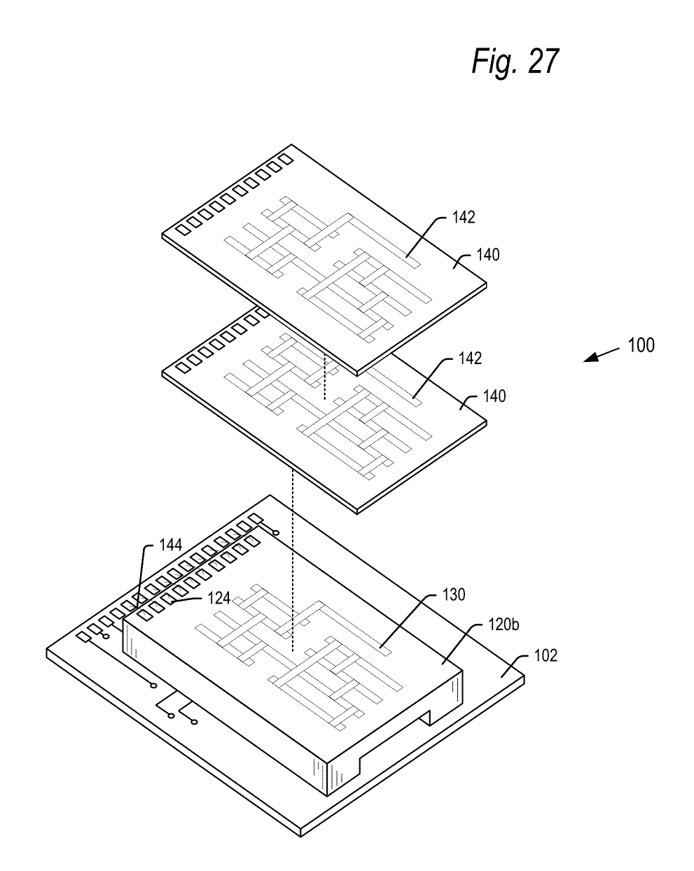

FIGS. 22-25 show various views of an IC bridge structure 120b formed by the processes of FIG. 18 or 19. The IC bridge structure 120b may be identical to the dummy bridge structure 120a, but may include an integrated circuit 130 in a surface opposite the trench 302, and may include die bond pads 124 (one of which is numbered in FIGS. 22 and 23). As with dummy bridge structure 120a, the IC bridge structure 120b may be mounted on the substrate 102, over the semiconductor die 114 as shown in FIG. 26. Thereafter, the IC bridge structure 120b may be wire bonded to the substrate 102 in step 212 (FIG. 3) via wire bonds 144 as shown in FIG. 27.

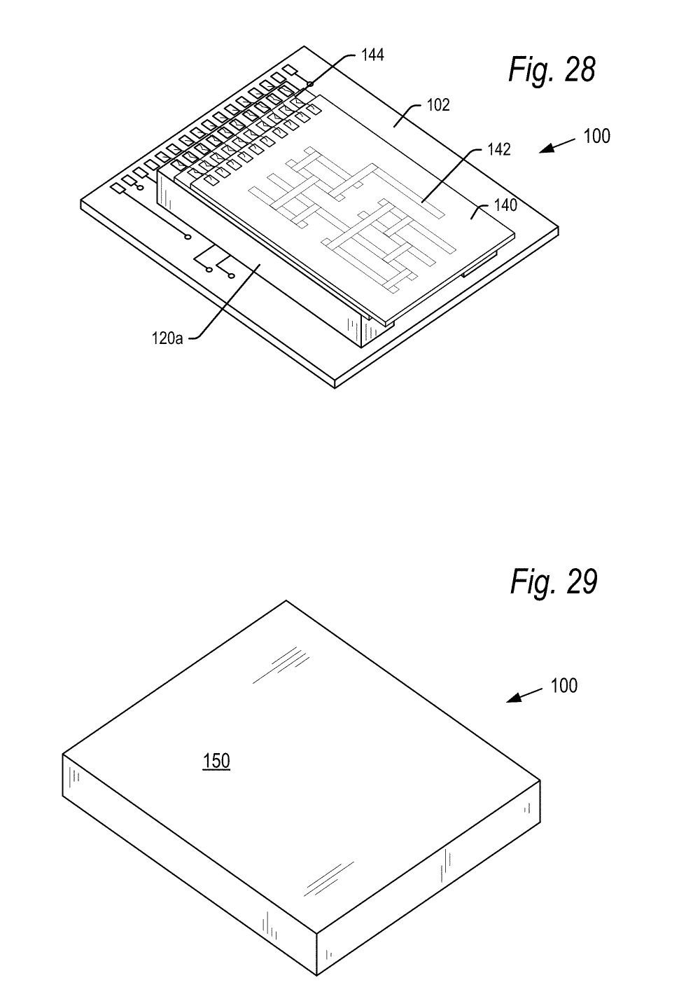

Additional semiconductor die 140 may then be added and wire bonded with wire bonds 144, as shown in FIGS. 27 and 28 and as described above. The number of semiconductor die 140 added may be more or less than two. Moreover, as IC bridge structure 120b may itself be a memory die in this embodiment, no additional semiconductor die 140 need be added in further embodiments. Instead of wire bonding the IC bridge structure 120b prior to mounting semiconductor die 140, the semiconductor die 140 may be mounted, and then the IC bridge structure 120b and semiconductor die 140 all wire bonded in the same process.

After the die stack is formed and wire bonded to bond pads on the substrate 102, the device 100 may be encased within the molding compound 150 (step 220), and singulated from the panel (step 224), to form a finished semiconductor device 100 as shown in FIG. 29. Thereafter, the device 100 may undergo electrical test and burn-in in step 226. In some embodiments, the finished package 100 may optionally be enclosed within a lid (not shown) in step 228.

The semiconductor device 100 may be used as an LGA (land grid array) package so as to be used as removable memory within a host device. In such embodiments, contact fingers (not shown) may be formed on a lower surface of the substrate 102 for mating with pins in a host device upon insertion of the semiconductor device 100 in the host device. Alternatively, the semiconductor device 100 may be used as a BGA (ball grid array) package so as to be permanently affixed to a printed circuit board within a host device. In such embodiments, solder balls (not shown) may be formed on contact pads on a lower surface of the substrate 102 for being soldered onto a printed circuit board of a host device.

In embodiments described above, the bridge structure may be formed from a semiconductor wafer 300 which has been partially processed or fully processed. It is understood that bridge structures 120 may be diced from a wafer 300 at any point after the wafer 300 has been cut, polished and formed with trenches 302.

The bridge structures 120 including trenches 302 allow the semiconductor die 114, for example a controller, to be mounted on the surface of the substrate 102, while providing a large, flat surface for mounting of additional memory die.

Moreover, forming the bridge structure from a semiconductor wafer provides further advantages. For example, as mentioned above, semiconductor device fabrication plants typically have resources for handling and processing semiconductor wafers. The vacuum chucks used to hold the wafer 300 as it is processed, the equipment for applying the die attach film to the second major surface of wafer 300, the wafer dicing equipment to cut the wafer 300 into respective bridge structures 120, and the pick and place robots for transferring the diced bridge structures onto the substrate 102 all commonly exist in a semiconductor device fabrication plant for handling other semiconductor wafers. This allows easy fabrication of the bridge structures 120 with little additional cost to the plant.

Moreover, by forming the bridge structures 120 from a semiconductor wafer, the bridge structures 120 may be made from the same material as the semiconductor die 140. For example, semiconductor die 114 may generate heat when operating, and this heat may cause the bridge structure 120 and semiconductor die 140 to expand. As the bridge structure 120 and semiconductor die 140 may be of the same material, they may have the same coefficient of thermal expansion. Thus, when the semiconductor heats the bridge structure and memory die on the bridge structure, they will expand to the same degree. It is understood that, where a dummy bridge structure 120a is used, materials other than semiconductor materials may be used. Some of these materials may have a coefficient of thermal expansion which is the same as or similar to semiconductor materials to prevent thermal mismatch.

In the description above, bridge structure 120 is either a dummy bridge structure or a functioning IC bridge structure. However, in further embodiments, the bridge structure 120 may be a semiconductor die with integrated circuits, but one which is not functioning as an electrical component. For example, it may happen that a semiconductor wafer is determined to be defective after forming the integrated circuits for a variety of reasons. In that case, instead of discarding the wafer, trenches 302 may be formed in the second major surface of the wafer as explained above, and the wafer diced into bridge structures. These bridge structures may include integrated circuits, but they may be used as dummy bridge structures which need not be wire bonded to the substrate 102. In a further embodiment, the integrated circuits may be sanded off of the first major surface of a defective wafer before or after formation of the trenches, and then the wafer diced into dummy bridge structures.

In embodiments described above, a single semiconductor die 114 such as a controller may be mounted to the substrate 102, and then enclosed within the trench 302 of the bridge structure 120. However, it is understood that different semiconductor die (including for example DRAM, NAND or other smaller memory die) and/or other electronic components may be mounted on the substrate and positioned within trench 302 in further embodiments.

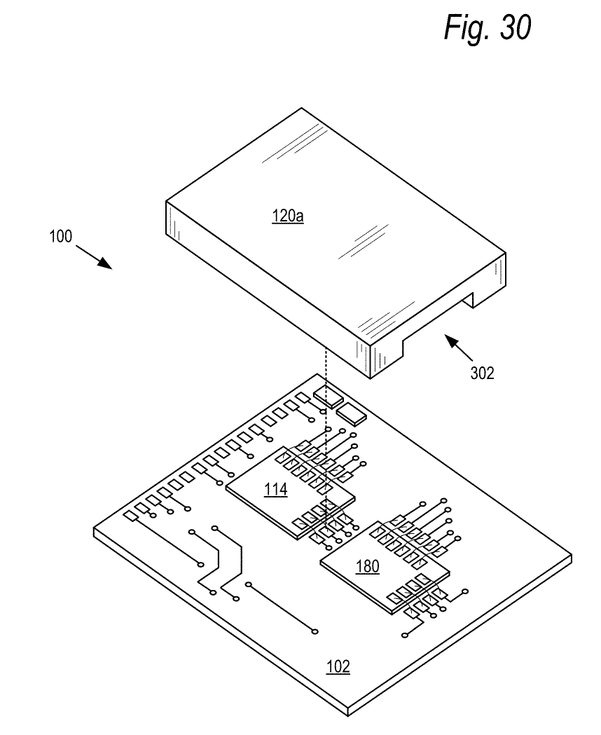

Additionally, FIG. 30 shows that two semiconductor die 114, 180 may be mounted within the trench 302. More than two semiconductor die and/or other electronic components may be mounted on the substrate in further embodiments which fit inside the trench 302 when the bridge structure 120 is mounted to the substrate.

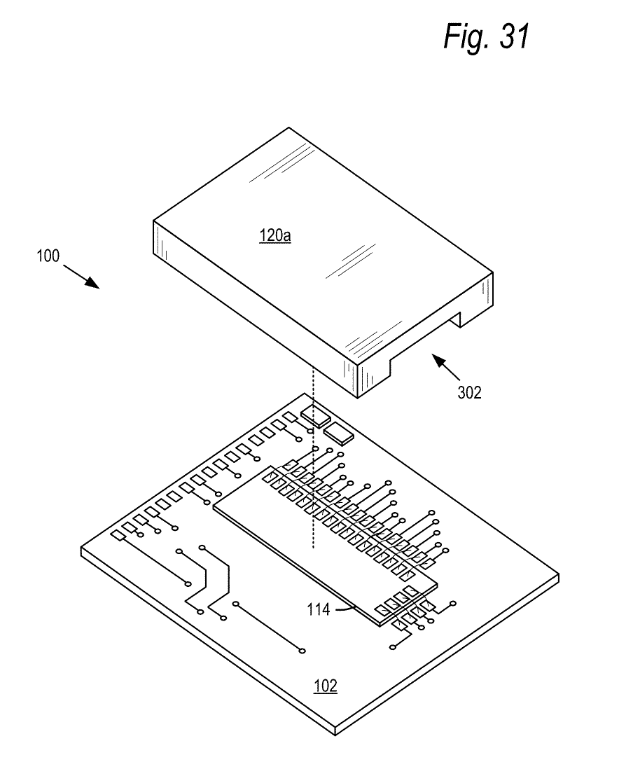

It is further understood that semiconductor die 114 may be different sizes within the trench 302. FIGS. 4 and 5 for example show a semiconductor die 114 that takes up relatively little of the trench 302. FIG. 31 shows a further embodiment of a semiconductor die 114 which takes up a relatively large portion of the trench 302.

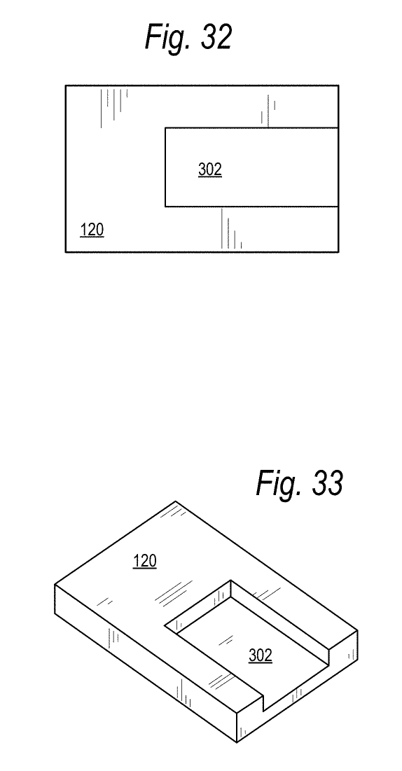

In embodiments described above, the trench 302 extends between opposed edges of the bridge structure 120. However, in a further embodiment, shown in FIGS. 32 and 33, the trench 302 may extend only partially between the opposed edges, open at one edge but not the opposed edge.

In summary, an example of the present technology relates to a bridge structure for a semiconductor device, the bridge structure comprising: a first surface; a second surface opposite the first surface; and a trench formed in the second major surface; wherein a material from which the bridge structure is formed is from a group consisting of a monocrystalline semiconductor element or compound and a polycrystalline semiconductor element or compound.

In a further example, the present technology relates to a semiconductor device, comprising: a substrate; a first semiconductor die mounted to a surface of the substrate; and a bridge structure mounted to the surface of the substrate, over the first semiconductor die, the bridge structure including a trench in a surface of the bridge structure adjacent the substrate, the trench extending from an edge of the bridge structure at least part way to an opposed edge of the bridge structure, the first semiconductor die fitting within the trench of the bridge structure.

In another example, the present technology relates to a semiconductor device, comprising: a substrate; a first semiconductor die mounted directly to a surface of the substrate; a bridge structure mounted directly to the surface of the substrate, over the first semiconductor die, the bridge structure including a trench in a surface of the bridge structure facing the substrate, the trench extending between opposed edges of the bridge structure, the first semiconductor die fitting within the trench in the bridge structure, the bridge structure comprising a dummy spacer layer from a partially processed wafer having a first thickness; and a group of one or more second semiconductor die from a semiconductor wafer having a second thickness less than the first thickness.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A method of forming a semiconductor device, comprising:
(a) mounting a semiconductor die on a surface of a substrate;
(b) forming a plurality of bridge structures from a wafer by the steps of:
(b1) forming a plurality of integrated circuits in the first surface of the wafer;
(b2) forming parallel rows of trenches in a second surface of the wafer opposite the first surface;
(c) singulating a bridge structure from the wafer, the singulated bridge structure comprising one or more integrated circuits of the plurality of integrated circuits in a first surface of the bridge structure, and a trench of the parallel rows of trenches, the trench extending from and between opposed edges of the bridge structure;
(d) mounting the bridge structure on the substrate with the semiconductor die fitting within the trench.

2. The method of claim 1, wherein said step (b2) of forming parallel rows of trenches in a second surface of the wafer opposite the first surface comprises the step of sawing the trenches into the second surface of the wafer.

3. The method of claim 1, wherein said step (b2) of forming parallel rows of trenches in a second surface of the wafer opposite the first surface comprises the step of sawing a trench of the parallel rows of trenches with multiple passes of a saw blade.

4. The method of claim 1, wherein said step (b2) of forming parallel rows of trenches in a second surface of the wafer opposite the first surface comprises the step of milling the trenches into the second surface of the wafer with a milling bit.

5. The method of claim 1, wherein said step (b2) of forming parallel rows of trenches in a second surface of the wafer opposite the first surface comprises the step of lasing the trenches into the second surface of the wafer with a laser.

6. The method of claim 1, wherein said step (b2) of forming parallel rows of trenches in a second surface of the wafer opposite the first surface comprises the step of etching the trenches into the second surface of the wafer.

7. The method of claim 1, wherein the step of forming a bridge structure comprises the step of forming a bridge structure from the group consisting of Group IV elemental semiconductors, Group IV compound semiconductors, Group VI elemental semiconductors, III-V semiconductors, II-VI semiconductors, I-VII semiconductors, IV-VI semiconductors, V-VI semiconductors, and II-V semiconductors.

8. The method of claim 1, wherein the step of forming a bridge structure comprises the step of forming a bridge structure with integrated circuits.

9. The method of claim 1, further comprising the step of mounting a plurality of semiconductor die on a surface of the bridge structure.

10. A method of forming a semiconductor device, comprising:
(a) mounting a semiconductor die on a surface of a substrate;
(b) forming a plurality of bridge structures from a wafer by the steps of:
(b1) forming a plurality of integrated circuits in the first surface of the wafer;
(b2) aligning locations of trenches to the plurality of integrated circuits formed in said step (b1);
(b3) forming parallel rows of trenches, aligned to the plurality of integrated circuits in said step (b2), in a second surface of the wafer opposite the first surface;
(c) singulating a bridge structure from the wafer, the singulated bridge structure comprising one or more integrated circuits of the plurality of integrated circuits in a first surface of the bridge structure, and a trench of the parallel rows of trenches, the trench extending from and between opposed edges of the bridge structure;
(d) mounting the bridge structure on the substrate with the semiconductor die fitting within the trench.

11. The method of claim 10, wherein the step (b2) of aligning locations of trenches to the plurality of integrated circuits comprises the step of mapping locations of integrated circuits on respective semiconductor die of the wafer and then aligning the positions of the trenches to the positions of the integrated circuits.

12. The method of claim 10, wherein said step of forming the bridge structure comprises the step of forming the bridge structure from a material from the group consisting of a monocrystalline semiconductor element or compound and a polycrystalline semiconductor element or compound.

13. The method of claim 10, wherein said step of forming the bridge structure comprises the step of forming the bridge structure with integrated circuits.

14. The method of claim 10, further comprising the step of mounting a plurality of memory die on the bridge structure.

15. The method of claim 10, wherein said step (b3) of forming parallel rows of trenches in a second surface of the wafer opposite the first surface comprises the step of sawing the trenches into the second surface of the wafer.
